(19) United States
(12) Patent Application Publication
(10) Pub. No.: US 2008/0159365 A1
(43) Pub. Date: Jul. 3, 2008

(54) Analog Conditioning of Bioelectric Signals

(76) Inventors: Branislav Dubocanin, San Jose, CA (US); Emir Delic, Lidcombe (AU)

Correspondence Address: FISH & RICHARDSON P.C., PO BOX 1022, MINNEAPOLIS, MN, 55440-1022, US

(21) Appl. No.: 11/960,545

(22) Filed: Dec. 19, 2007

Related U.S. Application Data
(60) Provisional application No. 60/871,768, filed on Dec. 22, 2006.

(51) Int. Cl. H03M 1/12; H03F 1/34

(52) U.S. Cl. 375/219; 330/109; 341/141

(57) ABSTRACT

An operational amplifier circuit is described. The operational amplifier circuit includes an operational amplifier, a high-pass filter portion, and a feedback loop, wherein the operational amplifier circuit is configured to output an amplified filtered version of a bio-signal. The operational amplifier includes a non-inverting input terminal, and an inverting input terminal, wherein the inverting input terminal and the non-inverting input terminal are configured to be coupled to a common reference potential through resistors. The high-pass filter portion is configured to receive a bio-signal as input and to provide input to the non-inverting input terminal of the operational amplifier. The feedback loop includes a low-pass filter portion, wherein the low-pass filter portion is configured to receive input from an output of the operational amplifier and to provide input to the inverting input terminal of the operational amplifier.

### CROSS-REFERENCE TO RELATED APPLICATIONS

This application claims priority to pending U.S. Provisional Application Ser. No. 60/871,768, entitled “Analog Conditioning of Bioelectric Signals,” filed on Dec. 22, 2006, the entire contents of which are hereby incorporated by reference.

### BACKGROUND

This invention relates to conditioning analog bioelectric signals.

An acquisition system to capture bioelectric signals, such as electroencephalograph (EEG) signals, generally consists of bio-signal detectors, analog conditioning, analog-to-digital conversion, and digital signal processing. Bio-signal detectors, such as electrodes, are used to acquire the analog bio-signals from a subject. The acquired bio-signals typically require analog conditioning to minimize noise, amplify the low voltage bio-signals to voltage levels compatible with an analog-to-digital converter (ADC), and filter out unnecessary portions of the spectrum. An ADC is used to convert the signal from analog to digital form. The digitized bio-signals can be further processed with a digital signal processor (DSP) or other computing device to display the rendered bio-signals or to provide input to clinical or non-clinical applications.

### SUMMARY

The present invention provides an inexpensive, low power, low noise hardware system for conditioning analog bio-signals. The invention retains high fidelity and accuracy while requiring fewer components relative to other systems. The reduction in components lowers cost and system complexity without sacrificing performance.

Operational amplifier circuits, chips, circuit boards, systems, and methods for conditioning analog bio-signals are provided. In one aspect, an operational amplifier circuit is described. The operational amplifier circuit includes an operational amplifier, a high-pass filter portion, and a feedback loop, wherein the operational amplifier circuit is configured to output an amplified filtered version of a bio-signal. The operational amplifier includes a non-inverting input terminal, and an inverting input terminal, wherein the inverting input terminal and the non-inverting input terminal are configured to be coupled to a common reference potential through resistors. The high-pass filter portion is configured to receive a bio-signal as input and to provide input to the non-inverting input terminal of the operational amplifier. The feedback loop includes a low-pass filter portion, wherein the low-pass filter portion is configured to receive input from an output of the operational amplifier and to provide input to the inverting input terminal of the operational amplifier.

In another aspect, a method of conditioning analog bio-signals is described. The method includes receiving at a high-pass filter portion a bio-signal, filtering the bio-signal with the high-pass filter portion to output a filtered version of the bio-signal, wherein the filtered version of the bio-signal includes frequency components above a first cutoff frequency, receiving at a non-inverting input terminal of an operational amplifier the filtered version of the bio-signal from the high-pass filter portion, amplifying the high-pass filtered version of the bio-signal with the operational amplifier, and outputting the amplified filtered version of the bio-signal. The operational amplifier has a feedback loop including a low-pass filter portion, wherein the low-pass filter portion provides a further filtered version of the bio-signal as input to the inverting input terminal of the operational amplifier. The further filtered version of the bio-signal includes frequency components above the first cutoff frequency and below a second cutoff frequency. The inverting input terminal and the non-inverting input terminal are configured to be coupled to a common reference potential through resistors. The operational amplifier is configured to provide an amplified filtered version of the bio-signal.

In yet another aspect, a chip for conditioning analog bio-signals is described. The chip includes a plurality of operational amplifiers to receive a plurality of analog bio-signals from a plurality of biosensors and generate amplified versions of the bio-signals as output. The chip also includes a multiplexer configured to generate an analog output by multiplexing the output from the plurality of operational amplifiers, and an analog-to-digital converter configured to generate a digital output by digitizing the analog signal from the multiplexer.

In one aspect, a chip for conditioning analog bio-signals includes a plurality of operational amplifier circuits, a multiplexer configured to generate an analog output by multiplexing the output from the plurality of operational amplifier circuits, and an analog-to-digital converter configured to generate a digital output by digitizing the analog signal from the multiplexer. Each operational amplifier circuit is configured to receive as input a different bio-signal and to generate an amplified filtered version of the bio-signal input.

In another aspect, a circuit board for conditioning analog bio-signals is described. The circuit board can have mounted thereon a chip and a wireless transceiver. The wireless transceiver is configured to receive the digitized output from the analog-to-digital converter of the chip and to transmit the digitized output to an external device.

In yet another aspect, a system is described. The system includes a headset and a circuit board, wherein the circuit board is electrically coupled to a plurality of bio-signal detectors.

In another aspect, a method of conditioning analog bio-signals is described. The method includes receiving bio-signals of a subject from a plurality of bio-signal detectors, filtering each bio-signal with a high-pass filter portion and a low-pass filter portion, amplifying each filtered version of a bio-signal with an operational amplifier to generate an amplified filtered version of the bio-signal, multiplexing the amplified filtered versions of the bio-signals with a multiplexer, and digitizing the analog signal with an analog-to-digital converter. The high-pass filter portion generates a first filtered version of the bio-signal including frequency components above a first cutoff frequency. The low-pass filter portion generates a second filtered version of the bio-signal including frequency components between the first cutoff frequency and a second cutoff frequency. The operational amplifier has a non-inverting input terminal and an inverting input terminal, wherein the non-inverting input terminal and the inverting input terminal configured to be coupled to a common reference potential through resistors. The multiplexer is configured to output an analog signal. The analog-to-digital converter is configured to generate digitized samples of the analog signal.

Implementations of the invention may include one or more of the following features. The bio-signals can include electroencephalograph (EEG) signals from a subject. The bio-signals can include frequency components with frequencies between about 0.1 Hertz and 160 Hertz. The common reference potential can be the potential of a subject as received from a location on the subject. The subject can be biased to the common reference potential through a capacitive input of the high-pass filter portion.

The high-pass filter portion can have a cutoff frequency of between about 0.1 and 0.2 Hertz. The high-pass filter portion can include a resistor and a capacitor, wherein the values of the resistor and capacitor determine the cutoff frequency for the high-pass filter portion. The high-pass filter portion can have a time constant that is less than 5 seconds.

The low-pass filter portion can have a cutoff frequency of between about 50 and 60 Hertz. The low-pass filter portion can include a resistor and a capacitor, wherein the values of the resistor and capacitor determine the cutoff frequency for the low-pass filter portion.

The operational amplifier can be configured to amplify the filtered version of the bio-signal by a factor between about 550 and 570. The operational amplifier can be a single gain stage amplifier. The operational amplifier can be a non-inverting amplifier, but the operational amplifier is generally not a differential amplifier or an instrumentation amplifier.

The chip can further include a processor to control the plurality of operational amplifier circuits, the multiplexer, a wireless transceiver, and the analog-to-digital converter. The chip can further include an anti-aliasing filter. The processor can be configured to process the digital output of the analog-to-digital converter. The chip can further include a driven right leg feedback circuit, wherein the driven right leg feedback circuit is configured to receive an analog signal as input and to generate an analog signal as output. Each circuit of the plurality of operational amplifier circuits can be in electrical communication with a single reference potential. The bio-signal input to each circuit of the plurality of operational amplifier circuits can be received from a bio-signal detector. The multiplexer can generate an analog output by multiplexing the output from all the operational amplifier circuits. The multiplexer can have a duty cycle of between about 40% and 60%. The multiplexer can have a duty cycle dependent on the rate of a clock signal driving the multiplexer. The analog-to-digital converter can be configured to generate a digital output by oversampling the analog signal from the multiplexer. The chip can further include a digital anti-aliasing filter for filtering the digital output of the analog-to-digital converter and a decimation device for decimating a filtered digital output of the digital anti-aliasing filter to a determined sampling rate.

The wireless transceiver can be a wireless 2.4 GHz device or a WiFi or Bluetooth device. The circuit board can be on a headset. The circuit board can be electrically coupled to 18 bio-signal detectors. The bio-signal detectors can be on a headset.

The method of conditioning analog bio-signals can further include processing the digitized samples with a processor and transmitting the processed bio-signals with a wireless transceiver to an external device. The method can further include preventing aliasing with a filter.

The details of one or more embodiments of the invention are set forth in the accompanying drawings and the description below. Other features, objects, and advantages of the invention will be apparent from the description and drawings, and from the claims.

### DESCRIPTION OF DRAWINGS

FIG. 1 is a schematic representation of an operational amplifier circuit for conditioning analog bio-signals.

FIG. 2 is a schematic diagram of a system for conditioning analog bio-signals.

FIG. 3 is a flow chart illustrating a method for conditioning analog bio-signals.

FIG. 4 is a schematic representation of a driven right leg (DRL) circuit.

FIG. 5 is a flow chart illustrating another method for conditioning analog bio-signals.

Like reference symbols in the various drawings indicate like elements.

### DETAILED DESCRIPTION

When transformed into electrical form, bio-signals tend to be described by low voltages, and acquisition of the bio-signals may capture unwanted noise, such as capacitively coupled common mode noise (e.g., power line interference at 50 Hz or 60 Hz), direct current (DC) offsets from bio-signal detectors, radio frequency interference, and skin and electrode interference noise. Furthermore, biological artifacts can also contaminate acquired bio-signals. For example, EEG signals, which typically range from 0.4 μV to 4 mV peak to peak, can be contaminated by the subject's EOG (eye movement), ECG (pulse), EMG (muscle activation), respiration, and many other forms of physiological artifacts. The unwanted noise or artifacts can be at a higher voltage than the desired bio-signal, which makes the acquisition process complicated and expensive.

Analog conditioning of the acquired bio-signals is used to minimize the interference from unwanted noise and artifacts, while preserving desired bio-signals. Acquisition systems typically reduce interference by filtering the acquired bio-signals, thus removing unwanted frequency components. For example, EEG signals have a frequency range of interest between about 0.1 Hz and 40 Hz, although some signals have been measured with frequencies as high as 160 Hz. The unwanted frequency components in EEG acquisition are the components outside this frequency range of interest. Analog conditioning of the low voltage bio-signals also includes amplification to make the bio-signals compatible with ADCs.

Attaining clean bio-signals often requires sophisticated analog and digital circuitry and superior bio-signal detectors. For example, EEG acquisition systems typically require multiple gain stages in their amplifier sections and use instrumentation grade amplifiers, which are a type of differential amplifier which provides high accuracy, high stability, and a high common mode rejection ratio (CMRR). As described before, typical EEG signals often ride on top of large common mode disturbances caused by power line noise and other artifacts. Large CMRR in the instrumentation amplifiers helps reject common mode disturbances, while retaining desired bio-signals.

Additionally, EEG acquisition systems generally filter the bio-signals after amplification. Amplification of noisy bio-signals prior to filtering can lead to saturation at the amplifier output. For example, saturation may occur when a high DC-offset is not filtered from the acquired bio-signal before amplification. Amplifier input terminals can also be referenced to different potentials, for example, to ground and to one-half the supply voltage, which requires operating the amplifier as a differential amplifier. Most implementations of EEG acquisition systems also require a separate ADC for each bio-signal channel. These implementations can require a large number of components which can result in higher cost with only marginal improvements in performance.

The present invention provides an inexpensive hardware system for conditioning analog bio-signals. The invention retains high fidelity while requiring fewer components relative to other implementations. The reduction in components lowers cost and system complexity.

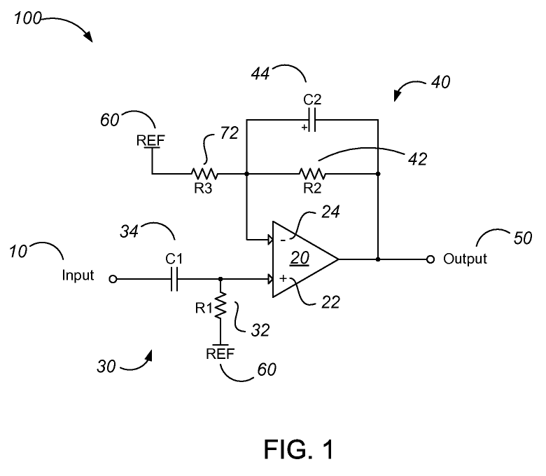

Referring to FIG. 1, a schematic representation of an operational amplifier circuit 100 for conditioning analog bio-signals is shown. The operational amplifier circuit 100 conditions analog bio-signals by removing unwanted frequency components and by amplifying the bio-signals.

The operational amplifier circuit 100 can receive an analog bio-signal, for example, an EEG signal, at input terminal 10. The operational amplifier circuit 100 includes an operational amplifier 20, a high-pass filter portion 30, and a low-pass filter portion 40. In some implementations, the operational amplifier 20 can be a low noise, low power operational amplifier, as described below. The operational amplifier circuit 100 generates an analog output signal, which is an amplified and filtered version of the analog bio-signal received at input terminal 10, at the output terminal 50.

In some implementations, such as for EEG acquisition, an operational amplifier 20 can be chosen to have low intrinsic noise. Many commercially available operational amplifiers have noise levels that are larger than 100 μV peak to peak for frequencies between about 0.1 Hz and 100 Hz. Operational amplifiers with noise levels this high generally cannot be used to acquire low voltage EEG signals. For EEG acquisition, an operational amplifier can be chosen to have a low noise level, for example, less than 10 μV peak to peak for frequencies below about 40 Hz.

The operational amplifier 20 has a non-inverting input terminal 22 and an inverting input terminal 24. The non-inverting input terminal 22 and the inverting input terminal 24 can be coupled to a common reference potential 60 though resistors R1 32 and R3 72, respectively. In certain implementations, the resistor R1 32 can have a resistance that is between about 800 kΩ and 1.2 MΩ, such as 1 MΩ. In some implementations, the resistor R3 72 can have a resistance that is less than about 5 kΩ, such as 1 kΩ. Coupling the input terminals of the operational amplifier 20 to a common reference potential 60 allows only the desired frequency components (i.e., the frequency components passed through both the high-pass filter portion 30 and the low-pass filter portion 40) to be amplified.

In some implementations, such as for EEG acquisition systems, the common reference potential 60 is the potential of a subject, such as a human, from which the EEG signals are received. The common reference potential is the same for the subject and the EEG acquisition system to minimize the possible potential difference between the subject and the electronic circuitry of the EEG acquisition system. The potential may be received from a location on the subject, e.g., on the subject's scalp. The common reference potential 60 can be acquired with a bio-signal detector, e.g., an electrode. Alternatively, the common reference potential 60 can be generated by averaging the common (DC) values of multiple bio-signals captured from the subject.

The high-pass filter portion 30 can receive the analog bio-signal as input at the input terminal 10. The high-pass filter portion 30 filters the input bio-signal 10 by removing frequency components of the input bio-signal 10 below a low cutoff frequency. In some implementations, the high-pass filter portion 30 includes the resistor R1 32 and a capacitor C1 34. The input terminal 10 can be coupled to the non-inverting input terminal 22 of the operational amplifier 20 through the capacitor C1 34. In certain implementations, the capacitor C1 34 can have a capacitance that is between about 500 nF and 2 μF, such as 1 μF. The values of the resistor R1 32 and the capacitor C 134 determine the frequency response of the high-pass filter portion 30, in particular, the cutoff frequency. The cutoff frequency (i.e., the −3 decibel (dB) point) is the frequency at which the power of the output of the high-pass filter portion 30 is one-half (i.e., −3 dB) the power of the output of frequencies in the pass band.

As an illustration, the frequency range of interest for EEG signals is generally between about 0.1 Hz and 40 Hz, although EEG signals have been measured with frequencies as high as 160 Hz. In some implementations, the cutoff frequency for the high-pass filter portion 30 is between about 0.1 and 0.2 Hz, such as 0.16 Hz. If the cutoff frequency is 0.1 Hz, the power output at 0.1 Hz is one-half the power output for frequencies in the pass band, i.e., the frequencies above about 0.1 Hz. Frequencies below 0.1 Hz will have output power at less than one-half the output power of the pass band, with output power approaching zero as the frequencies decrease. A high-pass filter portion 30 with a cutoff frequency of about 0.1 Hz can significantly reduce interference in the acquired bio-signal due to a DC offset from a bio-signal detector (e.g., an electrode). In some implementations, the DC offset can be further reduced by using a high quality active electrode for acquiring the EEG signal, resulting in a small DC offset component in the acquired signal which can be filtered by the high-pass filter portion 30.

The values of the resistor R1 32 and the capacitor C 134 also determine the time response of the high-pass filter portion 30. In some implementations, the time constant for the high-pass filter portion 30 is less than 5 seconds, such as about 1 second.

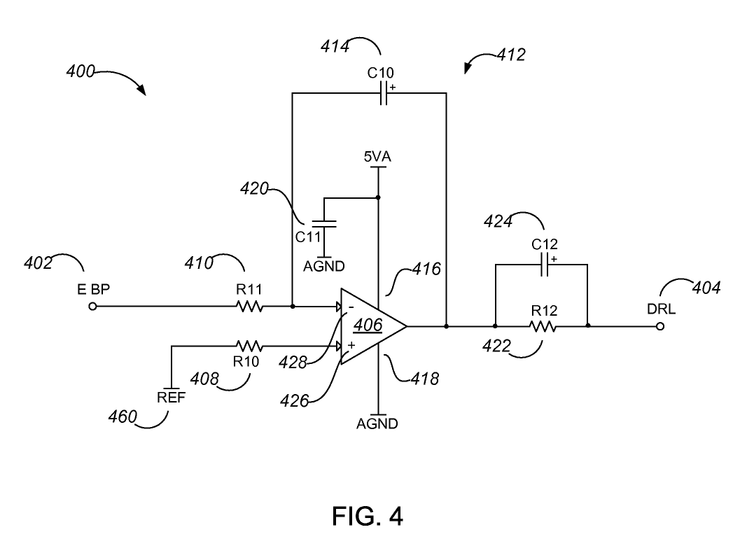

In some implementations, the common reference potential 60 can be generated inside the acquisition system, and the subject can be biased to the same potential. One way of biasing a subject to the reference potential is through a DRL circuit, as described below in reference to FIG. 4.

Alternatively, the subject can be biased to the reference potential through the capacitive interface at the input of the acquisition system. The reference potential REF will bias the capacitor C1 34 of the high-pass filter portion 30 through the resistor R1 32, and the potential at the input 10 will be equivalent to the reference potential REF through equilibrium. This technique allows a system to be designed without grounding (e.g., biasing electrodes), offering part reduction and considerable cost savings over more traditional methods. Additionally, a DRL circuit can be omitted if the subject is biased to the reference potential through the capacitive input. A DRL circuit can optionally be included to decrease the common mode noise susceptibility of the circuit.

The high-pass filter portion 30 provides as output a filtered version of the input bio-signal. The filtered version of the input bio-signal includes frequency components above the cutoff frequency of the high-pass filter portion 30. The filtered version is provided as input to the non-inverting input terminal 22 of the operational amplifier 20.

The output terminal 50 of the operational amplifier 20 is coupled to the inverting input terminal 24 of the operational amplifier through a feedback loop. The feedback loop includes the low-pass filter portion 40. The low-pass filter portion 40 can receive as input the output 50 of the operational amplifier 20. The low-pass filter portion 40 filters the output of the operational amplifier by removing frequency components above a high cutoff frequency. In some implementations, the low-pass filter portion 40 includes a resistor R2 42 and capacitor C2 44. In particular, the output terminal 50 can be coupled to the inverting input terminal 24 of the operational amplifier through the resistor R2 42 and the capacitor C2 44 in parallel. In certain implementations, the resistor R2 42 can have a resistance that is between about 400 kΩ and 800 kΩ, such as 560 kΩ. In some implementations, the capacitor C2 44 can have a capacitance that is between about 2 nF and 10 nF, such as 5.6 nF. The values of the resistor R2 42 and a capacitor C2 44 determine the frequency response of the low-pass filter portion 40, in particular, the cutoff frequency. Frequency components above this cutoff frequency will have output power at less than one-half the output power of the pass band, with output power approaching zero as the frequencies increase.

In some implementations, the cutoff frequency for the low-pass filter portion 40 is between about 50 Hz and 60 Hz, such as 51 Hz. For example, for EEG signals, the low-pass filter portion 40 with a cutoff frequency of about 50 Hz can reduce interference in the acquired bio-signal due to power line interference at 50 Hz or 60 Hz. In some embodiments, the cutoff frequency for the low-pass filter portion 40 is lower, e.g., between about 40 Hz and 50 Hz, or higher, e.g., between about 60 Hz and 70 Hz. In other implementations, the cutoff frequency for the low-pass filter portion 40 is above 160 Hz, for example, 165 Hz.

The low-pass filter portion 40 provides as output a filtered version of the operational amplifier output 50. The filtered version of the operational amplifier output 50 includes frequency components below the cutoff frequency of the low-pass filter portion 40 and above the cutoff frequency of the high-pass filter portion 30. The filtered version is provided as input to the inverting input terminal 24 of the operational amplifier 20.

The configuration of the low-pass filter in the feedback loop to the inverter input terminal 24 of the operational amplifier 20 provides amplification of the filtered bio-signal. The gain range is determined by the dynamic range of the bio-signal and the common reference potential 60. In some implementations, the gain can be a factor between about 550 and 570, such as 561. In other implementations, the gain can be lower, e.g., between about 500 and 550, or higher, e.g., between about 570 and 600. The operational amplifier circuit 100 passes as output 50 the amplified filtered bio-signals.

In some implementations, such as the exemplary implementation illustrated in FIG. 1, the operational amplifier 20 is a single stage amplifier. Using a single stage amplifier, as opposed to using multiple gain stages (e.g., the multiple gain stages using high accuracy and high cost instrumentation amplifiers), provides cost savings and less complexity. In some embodiments, the operational amplifier circuit 100 is configured to implement a single-input, single-output non-inverting amplifier, where the input bio-signal is coupled to the non-inverting input terminal 22 of the operational amplifier 20 through a high-pass filter portion 30.

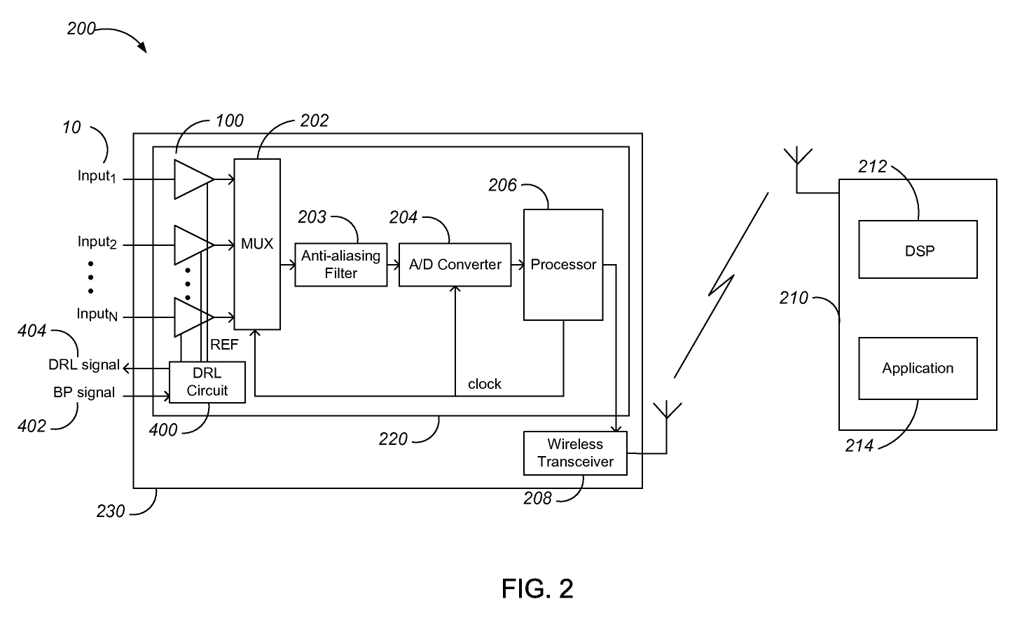

FIG. 2 is a schematic diagram of a system 200 for conditioning analog bio-signals. The system 200 includes a circuit board 230 and an external device 210. The system 200 receives as input N input signals on N input terminals 10, Input₁ to Input_{N}. The system is configured to receive analog bio-signals as inputs, for example, EEG signals. These bio-signals can be received from bio-signal detectors, such as electrodes. In some embodiments, the bio-signal detectors are acquired with active electrodes. The circuit board 230 can be mounted on a headset that also holds the electrodes which generate the input signals. An exemplary headset and electrodes are described further in Appendix A, which accompanies this application.

The circuit board 230 includes a chip 220 and a wireless transceiver 208. In some implementations, the circuit board 230 can include more than one chip 220. The chip 220 includes some combination of the following components, a plurality of operational amplifier circuits 100, a DRL feedback circuit 400, an analog time multiplexer (MUX) 202, an anti-aliasing filter 203, an ADC 204, and a processor (e.g., a microcontroller unit (MCU)) 206.

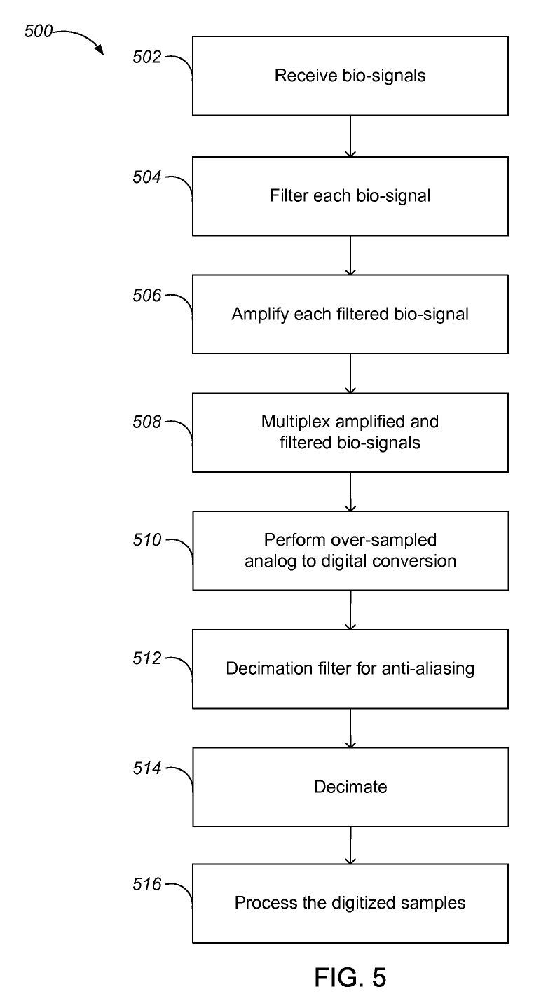

In some implementations, the design of the anti-aliasing filter 203 can be simplified through the use of over-sampling coupled with digital filtering and subsequent decimation, as described with reference to FIG. 5. In some embodiments the anti-aliasing filter 203 is omitted. In other embodiments, the anti-aliasing filter 203 can precede the multiplexer 202 in the signal path. In some embodiments, a chip 220 can include multiple MUXs, multiple ADCs, or multiple processors. In some implementations, the operational amplifier circuits 100 have the characteristics described above and are configured as illustrated in FIG. 1. In some embodiments, the operational amplifier circuit is configured differently than the exemplary amplifier circuit shown in FIG. 1.

There is one operational amplifier circuit 100 for each bio-signal input 10, and each operational amplifier circuit 100 receives a different bio-signal input 10. That is, in some embodiments, each amplifier circuit 100 is in electrical communication with a single biosensor or bio-signal detector. Each operational amplifier circuit 100 generates an amplified filtered version of the bio-signal input 10. In some implementations, the resistors 32, 42, 72 and capacitors 34, 44 are internal to the chip 220. In other implementations, one or more of the resistors 32, 42, 72 or capacitors 34, 44 can be discrete components mounted on the circuit board 230 and connected to appropriate leads of the chip 220 by wiring on the circuit board 230. In some implementations, each of the operational amplifier circuits 100 have the same common reference potential 60, as illustrated in FIG. 1. In some implementations, the common reference potential is generated on the chip 220 or the circuit board 230.

As described previously, most bio-signal acquisition systems require the use of instrumentation amplifiers with large CMRR in order to successfully reject large artifacts and common mode disturbances. However, the need for expensive and power inefficient instrumentation amplifiers can be eliminated by using active bio-signal detectors and a DRL feedback circuit with an input body potential (BP) signal.

Generally, in bio-signal acquisition systems, lines carry bio-signals from the detectors to an analog conditioning block. These signal lines typically have large impedances which result in the acquired bio-signals being contaminated with common mode interferences. Many bio-signal acquisition systems use instrumentation amplifiers to reject these common mode disturbances and retain only the desired bio-signals.

Active bio-signal detectors can reduce the large impedances of the signal lines to lower values. If active bio-signal detectors are used to lower the line impedance, common mode interferences will have significantly reduced amplitudes resulting in minimal impact. Use of active bio-signal detectors can reduce the need for expensive instrumentation amplifiers in bio-signal acquisition systems. In some implementations, bio-signal acquisition systems use biosensors that are completely passive, e.g., comprised solely of passive bio-signal detectors such as passive electrodes. In these acquisition systems, common mode interference can be rejected, e.g., by firmware in the headset.

In some embodiments, a DRL feedback circuit with an input BP signal references the bio-signal acquisition system to a common potential. A BP signal can be acquired, for example, with an electrode placed on a subject. However, this BP signal can vary with time. If a varying BP signal is directly used to reference the bio-signal acquisition system, the acquisition system would have to be robust to the signal variance, requiring complex and expensive amplifiers, such as instrumentation amplifiers.

A DRL feedback circuit with the BP signal as input biases the body of the subject to a common potential using the output of the DRL feedback circuit. The DRL feedback circuit can receive a varying BP signal as input and provide a DRL signal as output, wherein the input and output are electrically coupled to the body of the subject. If the BP signal begins to drift, the DRL feedback circuit can compensate for the drift with a DRL signal at the output, which is electrically coupled to the body of the subject. In some implementations, the DRL feedback circuit with BP signal can decrease susceptibility of the system to common mode disturbances by around 40 dB.

In some implementations, the chip 220 includes a DRL feedback circuit 400. FIG. 4 is a schematic representation of a DRL feedback circuit 400. The DRL feedback circuit 400 can receive an analog signal, for example, a BP, at input terminal 402. For example, an electrode placed on a subject can acquire a bio-signal to be used as the BP signal. The DRL feedback circuit 400 includes an operational amplifier 406, a feedback loop 412, three resistors 408, 410, 422, and three capacitors 414, 420, 424. In some implementations, the resistors 408, 410, 422 and capacitors 414, 420, 424 are internal to the chip 220. In other implementations, one or more of the resistors 408, 410, 422 or capacitors 414, 420, 424 can be discrete components mounted on the circuit board 230 and connected to appropriate leads of the chip 220, such as by wiring on the circuit board 230. The DRL feedback circuit 400 generates an analog output signal, the DRL signal, at output terminal 404. In some implementations, the output terminal 404 is electrically coupled to the body of a subject.

The operational amplifier 406 of the DRL feedback circuit 400 has a non-inverting input terminal 426, an inverting input terminal 428, a positive power supply terminal 416, and a negative power supply terminal 418. The non-inverting input terminal 426 can be coupled to a common reference potential 460 through resistor R10 408. In some implementations, the non-inverting input terminal 426 is coupled through multiple resistors to multiple reference potentials from multiple locations on a subject. The inverting input terminal 428 can be coupled to the BP signal at input terminal 402 through resistor R11 410. If the resistors R10 408 and R11 410 are chosen to be equal (i.e., have equal resistance), the common reference potential 460 is equal to the BP at input terminal 402. In certain implementations, the resistors R10 408 and R11 410 can have a resistance that is less than about 5 kΩ, such as 2 kΩ.

In some implementations, the common reference potential 460 of the DRL feedback circuit 400 is the same reference potential 60 of the operational amplifier circuits 100. For example, the chip 220 can internally route the common reference signal at terminal 460, which is equal to the BP signal at terminal 402 if the resistors 410 and 411 are equal, from the DRL feedback circuit 400 to the plurality of operational amplifier circuits 100. That is, the DRL feedback circuit 400 can be configured to provide the common reference potential 60 coupled to the non-inverting and inverting input terminals 22, 24 of each operational amplifier 20 of the operational amplifier circuits 100 (see FIG. 1). In particular, if resistors R10 408 and R11 410 are chosen to be equal, the DRL feedback circuit 400 can provide a reference potential equal to the BP as the common reference potential 60 to the operational amplifier circuits 100.

The negative power supply terminal 418 of the operational amplifier 406 can be coupled to ground. Power to the operational amplifier 406 can be supplied at the positive power supply terminal 416, which can be coupled to ground through capacitor C11 420. A feedback loop couples the output of the operational amplifier 406 to the inverting input terminal 428 through capacitor C10 414. The output of the operational amplifier 406 is coupled to the output of the DRL feedback circuit 400 through resistor R12 422 and capacitor C12 424 in parallel. In certain implementations, the resistor R12 422 can have a resistance that is between about 200 kΩ and 50 kΩ, such as 100 kΩ. In some implementations, the capacitors C10 414 and C12 424 can have a capacitance that is between about 2 nF and 0.5 nF, such as 1 nF. The capacitor C11 420 can have a capacitance that is between about 0.2 μF and 50 nF, such as 0.1 μF.

The amplified filtered bio-signals from the operational amplifier circuits 100 are received at the MUX 202. The MUX 202 generates an analog output by time-multiplexing (i.e., switching between) the amplified filtered bio-signals at its inputs. The MUX 202 can multiplex the amplified filtered bio-signals from all the operational amplifier circuits 100. Alternatively, the MUX 202 can multiplex the amplified filtered bio-signals from some fraction of the operational amplifier circuits 100.

The MUX 202 can receive a clock signal from processor 206. In some embodiments, the MUX 202 does not multiplex the amplified filtered bio-signals continuously (i.e., the MUX has a duty cycle that is less than 100%). For example, if the MUX has a duty cycle of 60%, the MUX would not transmit any signals 40% of the time. For 60% of the time, the MUX would alternate between the received amplified filtered bio-signals, transmitting the amplified filtered bio-signal from each operational amplifier circuit 100 for 1/N fraction of the 60% transmit time. The duty cycle of the MUX 202 can be dependent on the clock rate provided by the processor 206. For example, the processor clock rate can allow the MUX 202 to have a duty cycle of between about 40% and 60%, for example, 50%. A slower clock rate might require the MUX to have a higher duty cycle (e.g., 75% or 80%), while a faster clock rate might allow the MUX to have a lower duty cycle (e.g., 25% or 20%). Generally, the lower the duty cycle, the more power can be saved in operating the MUX.

The analog output of the MUX 202 is received at the ADC 204. The ADC 204, like the MUX 202, receives a clock signal from processor 206. The ADC 204 generates a digital output by digitizing the analog signal from the MUX 202.

In some implementations, additional filtering is performed by an anti-aliasing filter 203 prior to analog-to-digital conversion. That is, there is an anti-aliasing filter 203 after the MUX 202 but before the ADC 204. In these implementations, the analog output of the MUX is received at the anti-aliasing filter 203. The anti-aliasing filter 203 is configured to pass frequencies below the modulation frequency of the ADC. For example, a simple passive low-pass filter can be used with an ADC of sigma-delta type. If an anti-aliasing filter is used, the output of the anti-aliasing filter 203 is passed to the ADC 204.

The operational amplifier circuits 100, the MUX 202, the ADC 204, and the wireless transceiver 208 can be controlled by the processor 206. In some implementations, the processor 206 can provide processing of the digital output received from the ADC 204. For example, the processor 206 can package the digital output into packets prior to outputting the data to the wireless transceiver 208. In some implementations, the processor 206 provides a packaging function which includes mechanisms such as scrambling for improving the reliability of the packet transmission or encrypting for deterring attempts to tamper with the digital output.

The wireless transceiver 208 receives the digital data as packets from the processor 206 or as digital output directly from the ADC 204. In some embodiments, the wireless transceiver 208 is a wireless 2.4 GHz device or a WiFi or Bluetooth device. The wireless transceiver 208 transmits the digital data to an external device 210. The digital data can be transmitted to a host receiver, which can transmit an acknowledgment that signifies a successful transmission.

The external device 210 can be, for example, a dongle or a computer (e.g., a personal computer). The external device 210 can include a DSP or other processing device 212 for processing the digital signals derived from the analog bio-signals. Additionally, the external device 210 can include an application 214, such as a clinical or non-clinical application.

In some implementations, the circuit board 230 is on a headset. For example, for an EEG acquisition system, the EEG signals can be acquired using bio-signal detectors (e.g., electrodes) which are electrically coupled to the circuit board 230 located on a headset which can be worn by a subject. A suitable headset is shown in the accompanying appendix. In some embodiments, multiple (e.g., 18) bio-signal detectors are used for acquiring bio-signals. For example, 16 of the bio-signal detectors can be used to acquire EEG signals while one of the remaining two bio-signal detectors can be used to acquire the BP signal.

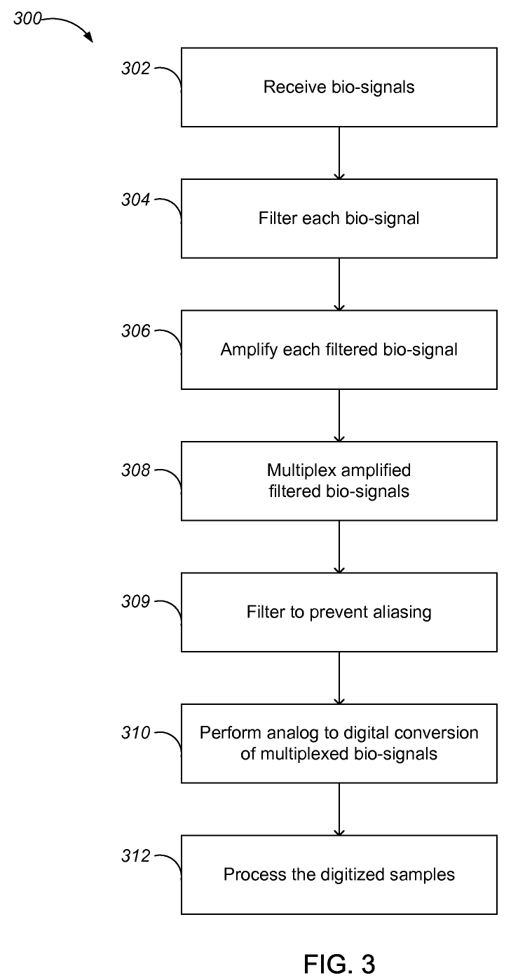

Referring to FIG. 3, a flow chart illustrates a method 300 for conditioning analog bio-signals. First, bio-signals of a subject are received (step 302) from a plurality of bio-signal detectors, for example, active electrodes. In some implementations, the bio-signal detectors are on a headset, as shown in the accompanying appendix. The bio-signals (e.g., EEG signals) can have the characteristics described above.

Each of the bio-signals is filtered (step 304) to remove unwanted noise or artifacts. Filtering can include high-pass filtering, e.g., for removing an unwanted DC offset, and low-pass filtering, e.g., for removing power line interference. In one implementation, each bio-signal is first high-pass filtered and then low-pass filtered. The high-pass filter generates a filtered version of the bio-signal with frequency components above the cutoff frequency of the high-pass filter. The filtered bio-signal is then further filtered with a low-pass filter. The output of the low-pass filter is a second filtered version of the bio-signal with frequency components between the cutoff frequency of the high-pass filter and a cutoff frequency of the low-pass filter. The high-pass and low-pass filters can have the characteristics (i.e., cutoff frequency, time constant, and components) described above.

Each bio-signal is also amplified (step 306) to increase the low voltage bio-signal to a voltage which is compatible with an ADC and to raise the bio-signal above the noise floor of the system. The filtering step can occur before or in conjunction with the amplification. In one implementation, the filtered bio-signal is amplified with an operational amplifier that has a non-inverting input terminal and an inverting input terminal, with both input terminals coupled to a common reference potential through resistors. In some implementations, the common reference potential is the potential of a subject received from a location on the subject. The operational amplifier produces an amplified filtered version of the bio-signal. The operational amplifier can be a single stage, non-inverting amplifier. Generally, the operational amplifier is not a differential or an instrumentation amplifier.

The amplified and filtered bio-signals are then time-multiplexed (step 308) with an analog MUX. The MUX can multiplex all the amplified filtered bio-signals or some fraction of the amplified filtered bio-signals to produce an analog output signal.

In some implementations, there is an anti-aliasing filter after the MUX and before the ADC. The anti-aliasing filter can filter the analog output signal of the MUX to prevent aliasing (step 309). For example, with an ADC of sigma-delta type, the anti-aliasing filter can be a simple passive low pass filter which restricts the bandwidth of the input signal to frequencies below the modulation frequency of the ADC. Alternatively, a more complex anti-aliasing filter can be implemented. If an anti-aliasing filter is used after the MUX, the output of the anti-aliasing filter is passed to the ADC. In some implementations, the anti-aliasing filter is before the MUX.

The analog time-multiplexed signal, composed of a plurality of amplified filtered bio-signals, is converted to digital form (step 310). An ADC can convert the analog time-multiplexed signal to digitized samples by sampling the analog signal (i.e., measuring the analog signal at regular intervals) and digitizing the samples (i.e., converting the measured value to a value in a discrete set). In some implementations, the ADC samples the analog time-multiplexed signal in a range of about 5 to 20 kHz.

The digitized samples can be processed (step 312), such as assembled into packets. The processed digitized samples can be transmitted with a wireless transceiver to an external device. In some embodiments, the wireless transceiver is a wireless 2.4 GHz device or a WiFi or Bluetooth device.

Referring to FIG. 5, a flow chart illustrates another method 500 for conditioning analog bio-signals. Typically, common mode disturbances, such as 50 Hz or 60 Hz power line noise, can be much larger than the bio-signals of interest. These common mode disturbances can introduce aliasing spikes into the digitized signals even if an anti-aliasing filter (e.g., anti-aliasing filter 203 of FIG. 2) is used before analog to digital conversion. Filtering the analog bio-signal with a first order low pass filter (e.g., the low-pass filter portion 40 of the operational amplifier circuit 100 of FIG. 1) can provide attenuation on the order of 6 dB per octave in the stopband of the filter. However, this attenuation is sometimes not sharp enough to sufficiently attenuate the aliasing components of the common mode noise disturbances, allowing the noise disturbances to distort the digitized bio-signals waveform through aliasing. Method 500 for conditioning analog bio-signals offers an inexpensive solution to this problem by oversampling, sharp digital filtering, and decimation.

Similar to method 300 of FIG. 3, bio-signals of a subject are received (step 502), filtered to remove DC offsets and noise and to limit the aliasing of analog to digital conversion (step 504), amplified (step 506), and multiplexed (step 508). The analog time-multiplexed signal, composed of a plurality of amplified and filtered bio-signals, is converted to digital form in over-sampling mode (step 510). In some implementations, the input signal is over-sampled by a factor of between 8 and 16. In some implementations, step 504 includes filtering with an analog low pass filter, e.g., the low-pass filter portion 40 of FIG. 1. In some implementations, an optional anti-aliasing filter (e.g., the anti-aliasing filter 203 of FIG. 2) can also be used to limit the aliases due to higher frequency components.

The over-sampled digital signal is decimation filtered for anti-aliasing (step 512). A finite impulse response (FIR) filter can be designed for a digital signal to attenuate common mode disturbances (e.g., power line noise) by a large amount at a much lower cost than designing an analog filter for each channel to achieve the same attenuation. For example, a 96-tap, rectangular low-pass FIR filter with a passband to 49 Hz, a stopband from 49 Hz to 52 Hz, and a stopband ripple of 40 dB can be used to lower the aliasing contributions of power line noise. In contrast, an equivalent analog anti-aliasing filter that would precede an ADC (e.g., ADC 204 of FIG. 2) would be very complex and would require hundreds of components to implement.

The filtered data is then down-sampled (decimated) to the intended sampling rate (step 514). For example, every eighth sample can be dropped to lower the sampling rate by a factor of 8. The resulting data is generally free from the power line noise and beat frequencies that would have been contributed through aliasing. The decimated filtered data can be further processed (step 516), as described with respect to method 300 of FIG. 3.

A number of embodiments of the invention have been described. Nevertheless, it will be understood that various modifications may be made without departing from the spirit and scope of the invention. Accordingly, other implementations are within the scope of the following claims.

What is claimed is:

1. An operational amplifier circuit for conditioning analog bio-signals comprising:
an operational amplifier, wherein the operational amplifier comprises:
a non-inverting input terminal; and
an inverting input terminal, wherein the inverting input terminal and the non-inverting input terminal are configured to be coupled to a common reference potential through resistors;
a high-pass filter portion configured to receive a bio-signal as input, the high-pass filter portion further configured to provide input to the non-inverting input terminal of the operational amplifier; and
a feedback loop comprising a low-pass filter portion, the low-pass filter portion configured to receive input from an output of the operational amplifier, the low-pass filter portion further configured to provide input to the inverting input terminal of the operational amplifier,
wherein the operational amplifier circuit is configured to output an amplified filtered version of the bio-signal.

2. The operational amplifier circuit of claim 1, wherein the bio-signals comprise electroencephalograph (EEG) signals from a subject.

3. The operational amplifier circuit of claim 1, wherein the bio-signals comprise frequency components with frequencies between about 0.1 Hertz and 160 Hertz.

4. The operational amplifier circuit of claim 1, wherein the common reference potential is a potential of a subject as received from a location on the subject.

5. The operational amplifier circuit of claim 1, wherein a potential of a subject is biased to the common reference potential through a capacitive input of the high-pass filter portion.

6. The operational amplifier circuit of claim 1, wherein the high-pass filter portion has a cutoff frequency of between about 0.1 and 0.2 Hertz.

7. The operational amplifier circuit of claim 1, wherein the high-pass filter portion is comprised of a resistor and a capacitor, wherein the values of the resistor and capacitor determine the cutoff frequency for the high-pass filter portion.

8. The operational amplifier circuit of claim 1, wherein the high-pass filter portion has a time constant that is less than 5 seconds.

9. The operational amplifier circuit of claim 1, wherein the low-pass filter portion has a cutoff frequency of between about 50 and 60 Hertz.

10. The operational amplifier circuit of claim 1, wherein the low-pass filter portion is comprised of a resistor and a capacitor, wherein the values of the resistor and capacitor determine the cutoff frequency for the low-pass filter portion.

11. The operational amplifier circuit of claim 1, wherein the operational amplifier is configured to amplify the filtered version of the bio-signal by a factor between about 550 and 570.

12. The operational amplifier circuit of claim 1, wherein the operational amplifier is a single gain stage amplifier.

13. The operational amplifier circuit of claim 1, wherein the operational amplifier is a non-inverting amplifier.

14. The operational amplifier circuit of claim 1, wherein the operational amplifier is not a differential amplifier or an instrumentation amplifier.

15. A method of conditioning analog bio-signals comprising:
receiving at a high-pass filter portion a bio-signal;
filtering the bio-signal with the high-pass filter portion to output a filtered version of the bio-signal, the filtered version of the bio-signal comprised of frequency components above a first cutoff frequency;
receiving at a non-inverting input terminal of an operational amplifier the filtered version of the bio-signal from the high-pass filter portion;
amplifying the high-pass filtered version of the bio-signal with the operational amplifier, the operational amplifier having a feedback loop comprised of a low-pass filter portion, the low-pass filter portion providing a further filtered version of the bio-signal as input to the inverting input terminal of the operational amplifier, the further filtered version of the bio-signal comprised of frequency components above the first cutoff frequency and below a second cutoff frequency, the inverting input terminal and the non-inverting input terminal configured to be coupled to a common reference potential through resistors, wherein the operational amplifier is configured to provide an amplified filtered version of the bio-signal; and
outputting the amplified filtered version of the bio-signal.

16. The method of claim 15, wherein the bio-signal comprises an electroencephalograph (EEG) signal from a subject.

17. The method of claim 15, wherein the bio-signal comprises frequency components with frequencies between about 0.1 Hertz and 160 Hertz.

18. The method of claim 15, wherein the common reference potential is a potential of a subject as received from a location on the subject.

19. The method of claim 15, wherein a potential of a subject is biased to the common reference potential through a capacitive input of the high-pass filter portion.

20. The method of claim 15, wherein the operational amplifier is configured to amplify the filtered version of the bio-signal by a factor between about 550 and 570.

21. The method of claim 15, wherein amplifying the high-pass filtered version of the bio-signal is performed with a single gain stage amplifier.

22. The method of claim 15, wherein amplifying the high-pass filtered version of the bio-signal is performed with a non-inverting amplifier.

23. A chip for conditioning analog bio-signals comprising:
a plurality of operational amplifier circuits, each operational amplifier circuit being the operational amplifier circuit of claim 1, wherein each operational amplifier circuit is configured to receive as input a different bio-signal, each operational amplifier further configured to generate an amplified filtered version of the bio-signal input;
a multiplexer configured to generate an analog output by multiplexing the output from the plurality of operational amplifier circuits; and
an analog-to-digital converter configured to generate a digital output by digitizing the analog signal from the multiplexer.

24. The chip of claim 23 further comprising a processor to control the plurality of operational amplifier circuits, the multiplexer, a wireless transceiver, and the analog-to-digital converter.

25. The chip of claim 24, wherein the processor is configured to process the digital output of the analog-to-digital converter.

26. The chip of claim 23 further comprising an anti-aliasing filter.

27. The chip of claim 23 further comprising a driven right leg feedback circuit, wherein the driven right leg feedback circuit is configured to receive an analog signal as input, the driven right leg feedback circuit further configured to generate an analog signal as output.

28. The chip of claim 23, wherein each circuit of the plurality of operational amplifier circuits is in electrical communication with a single reference potential.

29. The chip of claim 23, wherein the bio-signal input to each circuit of the plurality of operational amplifier circuits is received from a bio-signal detector.

30. The chip of claim 23, wherein the multiplexer generates an analog output by multiplexing the output from all the operational amplifier circuits.

31. The chip of claim 23, wherein the multiplexer has a duty cycle of between about 40% and 60%.

32. The chip of claim 23, wherein the multiplexer has a duty cycle dependent on the rate of a clock signal driving the multiplexer.

33. The chip of claim 23, where the analog-to-digital converter is configured to generate a digital output by oversampling the analog signal from the multiplexer.

34. The chip of claim 33 further comprising a digital anti-aliasing filter for filtering the digital output of the analog-to-digital converter and a decimation device for decimating a filtered digital output of the digital anti-aliasing filter to a determined sampling rate.

35. A circuit board for conditioning analog bio-signals comprising:
the chip of claim 23; and
a wireless transceiver configured to receive the digitized output from the analog-to-digital converter of the chip and to transmit the digitized output to an external device.

36. The circuit board of claim 35, wherein the chip further comprises a processor configured to process the digitized output of the analog-to-digital converter, the processor further configured to provide a processed output to the wireless transceiver.

37. The circuit board of claim 35, wherein the wireless transceiver is a wireless 2.4 GHz device or a WiFi or Bluetooth device.

38. The circuit board of claim 35, wherein the circuit board is on a headset.

39. A chip for conditioning analog bio-signals comprising:
a plurality of operational amplifiers to receive a plurality of analog bio-signals from a plurality of biosensors and generate amplified versions of the bio-signals as output;
a multiplexer configured to generate an analog output by multiplexing the output from the plurality of operational amplifiers;
an anti-aliasing filter configured to generate a filtered output by filtering the analog output from the multiplexer; and
an analog-to-digital converter configured to generate a digital output by digitizing the filtered output from the anti-aliasing filter.

40. The chip of claim 39 further comprising a driven right leg feedback circuit, wherein the driven right leg feedback circuit is configured to receive an analog signal as input, the driven right leg feedback circuit further configured to generate an analog signal as output.

41. A system comprising:
a headset; and
the circuit board of claim 35, wherein the circuit board is electrically coupled to a plurality of bio-signal detectors.

42. The system of claim 41, wherein the circuit board is electrically coupled to 18 bio-signal detectors.

43. A method of conditioning analog bio-signals comprising:
receiving bio-signals of a subject from a plurality of bio-signal detectors;
filtering each bio-signal with a high-pass filter portion and a low-pass filter portion, the high-pass filter portion generating a first filtered version of the bio-signal comprised of frequency components above a first cutoff frequency, the low-pass filter portion generating a second filtered version of the bio-signal comprised of frequency components between the first cutoff frequency and a second cutoff frequency;
amplifying each filtered version of a bio-signal with an operational amplifier to generate an amplified filtered version of the bio-signal, the operational amplifier having a non-inverting input terminal and an inverting input terminal, the non-inverting input terminal and the inverting input terminal configured to be coupled to a common reference potential through resistors;
multiplexing the amplified filtered versions of the bio-signals with a multiplexer, the multiplexer configured to output an analog signal; and
digitizing the analog signal with an analog-to-digital converter, the analog-to-digital converter configured to generate digitized samples of the analog signal.

44. The method of claim 43 further comprises processing the digitized samples with a processor.

45. The method of claim 44 further comprises transmitting the processed bio-signals with a wireless transceiver to an external device.

46. The method of claim 43 further comprises preventing aliasing with a filter.

47. The method of claim 43, wherein the bio-signal detectors are on a headset.

48. The method of claim 43, wherein the wireless transceiver is a wireless 2.4 GHz device or a WiFi or Bluetooth device.

49. The method of claim 43, where digitizing the analog signal with the analog-to-digital converter further comprises:
oversampling the analog signal with the analog-to-digital converter.

50. The method of claim 49 further comprising:
filtering the digitized samples with a digital anti-aliasing filter, the digital anti-aliasing filter configured to generate filtered digital samples; and
decimating the filtered digital samples to a determined sampling rate.
